(19) United States
(12) Patent Application Publication
(10) Pub. No.: US 2008/0036033 A1
(43) Pub. Date: Feb. 14, 2008

(54) One-time programmable memory

(75) Inventors: Akira Ito, Irvine, CA (US); Henry Chen, Irvine, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/889,174

(22) Filed: Aug. 9, 2007

Related U.S. Application Data
(60) Provisional application No. 60/836,696, filed on Aug. 10, 2006.

(51) Int. Cl. H01L 27/112; H01L 21/82

(52) U.S. Cl. 257/530; 438/131; 257/E27.102; 257/E21.666

(57) ABSTRACT

A one-time programmable memory. The memory has a substrate, a diffused electrode disposed on the substrate, a shallow trench isolation (STI) region formed on the substrate, a insulator formed on the STI region and the substrate, and a second electrode. The insulator separates the second electrode from the diffused electrode. At least a part of the second electrode overlaps at least a part of the STI region.

### CROSS REFERENCE TO RELATED APPLICATIONS

This application claims benefit of U.S. Provisional Patent Application No. 60/836,696, filed on Aug. 10, 2006, and this application is related to U.S. patent application Ser. No. 11/094,269, filed on Mar. 31, 2005, which is a continuation of U.S. patent application Ser. No. 10/773,263 (now U.S. Pat. No. 6,902,958 that issued on Jun. 7, 2005), filed on Feb. 9, 2004, which is a continuation of U.S. patent application Ser. No. 10/197,437 (now U.S. Pat. No. 6,700,176 that issued on Mar. 2, 2004), filed on Jul. 18, 2002, all of which are incorporated by reference herein in their entireties.

### FIELD OF THE INVENTION

The present invention generally relates to information storage. More specifically, the present invention relates to non-volatile memory.

### BACKGROUND OF THE INVENTION

In the field of data storage, there are two general types of storage devices. The first type of storage device is volatile memory. Volatile memory loses stored information the instant power is removed from the volatile memory circuit. The second type of storage device is non-volatile memory. Non-volatile memory retains stored information even after power is removed from the non-volatile memory circuit. Some non-volatile memory designs permit reprogramming while other designs only permit one-time programming. Thus, one form of non-volatile memory is a One-Time Programmable (OTP) device.

An OTP device is also known as an antifuse. An antifuse is a device that continuously conducts after having been once subjected to a voltage in excess of a threshold voltage, also known as a programming voltage. In other words, an antifuse conducts only after it has been “blown.” An OTP device may be formed from a conventional metal-oxide-semiconductor field-effect transistor (MOSFET).

FIG. 1 illustrates a conventional MOSFET 100 configured as an OTP device. The MOSFET 100 consists of an doped polysilicon gate 102, a well region 104, as well as both source 106 and drain 108 regions formed by diffusion of dopant in a silicon substrate 110. The channel region 103 is a part of the well 104 in which a channel may form during transistor operation of the MOSFET 100. Thus, the MOSFET 100 has two diffused electrodes—the source 106 and drain 108 regions. The channel region 103 separates the source 106 from the drain 108 in a lateral direction. A layer of dielectric gate oxide 112 separates the polysilicon gate 102 from the channel 103. The MOSFET 100 is designed to have a high impedance between the gate 102 and the source 106, drain 108, and well 104.

When used as an OTP device, the MOSFET 100 is programmed by stressing the dielectric gate oxide 112 beyond a critical electrical field. Programming ruptures the dielectric gate oxide 112, greatly reducing a resistance of the dielectric gate oxide 112 from that of a non-ruptured gate oxide 112. The resistance of the gate oxide 112 decreases because a part of the gate oxide 112 forms permanent current paths 114A-D by diffusion of the polysilicon gate material or silicon from the substrate 110 into the gate oxide 112. Thus, the MOSFET 100 may be used as an OTP device by utilizing the gate oxide 112 as an antifuse element. In the MOSFET 100, after rupture of the gate oxide 112, permanent current paths 114 exist between the gate 102 and the well 104. Alternatively, permanent current paths 114 may exist between the gate 102 and either the source 106 or drain 108 after fusing as shown in FIG. 1.

The MOSFET 100 OTP device is challenging to read. The permanent current paths 114 through the gate oxide 112 have varying resistance that is determined in part by location. Lower resistance paths 114A, 114D tend to be between the gate 102 and the source 106 or between the gate 102 and the drain 108. Conversely, when the permanent current paths 114B, 114C are formed between the gate 102 and the well 104, the resistance is higher. These variations in current path resistance make the MOSFET 100 OTP device challenging to read.

An OTP device should be as small as possible to maximize memory density. However, the MOSFET 100 has three electrodes, the gate 102, source 106, and drain 108, as well as associated structures that connect the gate 102, source 106, and drain 108 to other circuits. The need for at least three electrodes and their associated structures makes the MOSFET 100 OTP device large.

Therefore, what is needed is a one-time programmable memory that has low variability of permanent current path resistance as well as a size smaller than that of the MOSFET 100 OTP device. It is also desirable that the one-time programmable memory be compatible with conventional CMOS manufacturing processes to ease a transition from manufacture of the MOSFET 100 OTP device as well as easily integrate the one-time programmable device with other CMOS circuitry.

Further, what is needed is a one-time programmable memory that overcomes the shortcomings described above.

### BRIEF SUMMARY OF THE INVENTION

In an embodiment, there is a one-time programmable memory. The memory element has a substrate, a diffused electrode disposed on the substrate, a shallow trench isolation (STI) region formed on the substrate, an insulator formed on the STI region and the substrate, and a second electrode. The insulator separates the second electrode from the diffused electrode. At least a part of the second electrode overlaps at least a part of the STI region.

Additional features and advantages of the invention are set forth in the description that follows, and in part are apparent from the description, or may be learned by practice of the invention. The advantages of the invention are realized and attained by the structure and particularly pointed out in the written description and claims hereof as well as the appended drawings.

Both the foregoing general description and the following detailed description are exemplary and explanatory and are intended to provide further explanation of the invention as claimed.

### BRIEF DESCRIPTION OF THE DRAWINGS/FIGURES

The accompanying drawings, which are incorporated herein and form a part of the specification, illustrate the invention and, together with the description, further serve to explain the principles of the invention and to enable a person skilled in the pertinent art to make and use the invention.

FIG. 1 illustrates a conventional MOSFET 100 configured as a One-Time Programmable (OTP) device.

FIGS. 2A-C illustrate an OTP memory according to an embodiment of the invention.

FIG. 3 is a flowchart of an exemplary method for manufacturing an OTP memory.

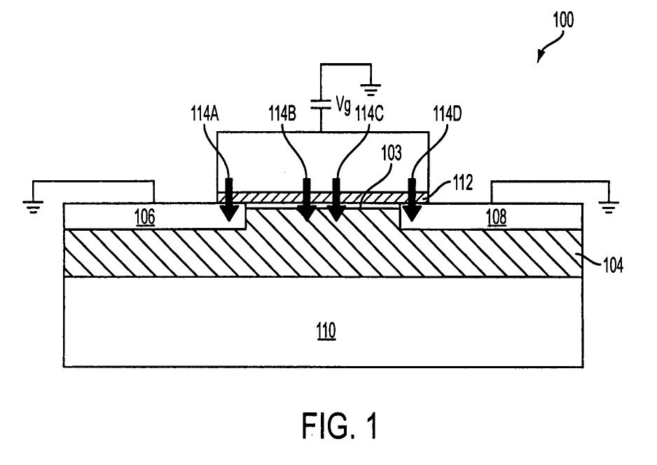

The invention is described with reference to the accompanying drawings. The drawing in which an element first appears is typically indicated by the leftmost digit(s) in the corresponding reference number.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims.

The embodiment(s) described and references in the specification to “one embodiment,” “an embodiment,” “an example embodiment,” etc., indicate that the embodiment(s) described may include a particular feature, structure, or characteristic. However, every embodiment may not necessarily include the particular feature, structure, or characteristic. Moreover, such phrases are not necessarily referring to the same embodiment. When a particular feature, structure, or characteristic is described in connection with an embodiment, it is understood that it is within the knowledge of one skilled in the art to effect such feature, structure, or characteristic in connection with other embodiments, whether or not explicitly described.

Conventional electronics, semiconductor manufacturing, memory technologies and other functional aspects of the devices (and components of the individual operating components of the devices) may not be described in detail herein for the sake of brevity. Furthermore, for purposes of brevity, the invention is described herein as pertaining to a memory for use in an electrical or electronic system. It should be appreciated that many other manufacturing techniques could be used to create the memory described herein, and that the techniques described herein could be used to fabricate individual devices, discrete circuits, memory arrays, or other devices. Further, the techniques would be suitable for application in electrical systems, optical systems, consumer electronics, industrial electronics, wireless systems, appliances, space applications, or any other application.

The terms anti-fuse and memory are used interchangeably in this field. The terms storage or programmable when coupled with the terms cell, element, memory or device are used interchangeably in this field. The terms chip, integrated circuit, monolithic device, semiconductor device and microelectronic device are used interchangeably in this field.

The terms pin, pad, contact, and lead refer to input and/or output terminals of a connector, device, chip, printed circuit, or the like, which are used to provide electrical connection to one or more connectors, devices, chips, printed circuits, or the like.

The terms metal line, trace, wire, contact, conductor, signal path and signaling medium are all related. These related terms are generally interchangeable and appear in order from most specific to most general. In this field, metal lines are sometimes referred to as traces, wires, lines, interconnect or simply metal. Metal lines, generally aluminum (Al) or an alloy of Al and copper (Cu), are conductors which provide signal paths for coupling, or interconnecting, electrical circuitry. Conductors other than metal are available in microelectronic devices. Materials such as doped polysilicon, doped single-crystal silicon (often referred to simply as diffusion, regardless of whether such doping is achieved by thermal diffusion or ion implantation), titanium (Ti), molybdenum (Mo), or refractory metal silicides are examples of other conductors. Signaling medium is the most general term and encompasses the others. The present invention is applicable to all of these terms as they are generally understood in the field.

Moreover, it should be understood that the spatial descriptions (e.g., “above”, “below”, “up”, “down”, “top”, “bottom”, “beneath”, “across”, etc.) made herein are for purposes of illustration only, and that practical memories may be spatially arranged in any orientation or manner. Arrays of memories may also be formed by connecting them in appropriate ways and with appropriate devices.

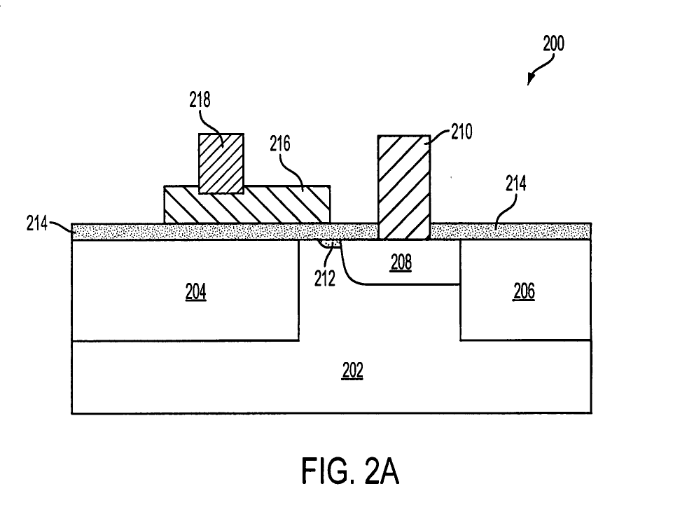

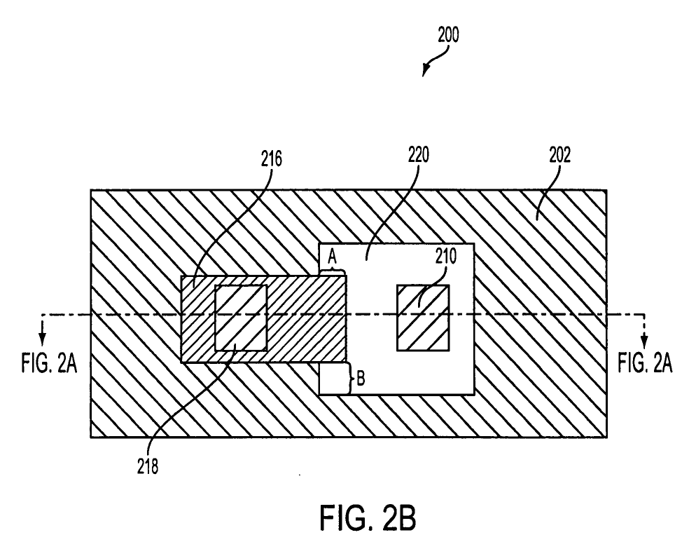

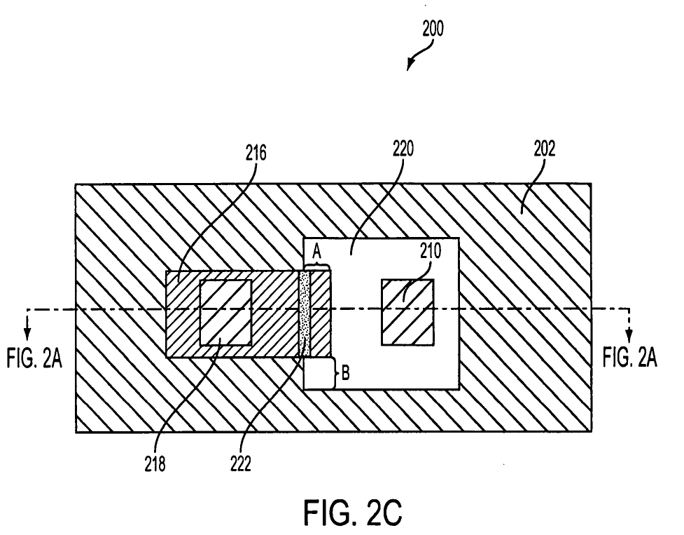

FIGS. 2A-C illustrate an OTP memory 200, also known as an antifuse, according to an embodiment of the invention. FIG. 2A illustrates a side view of a cross-section of the OTP memory 200. FIG. 2B illustrates a top view of the OTP memory 200. The OTP memory 200 has a shallow trench isolation (STI) region 204 which directs formation of low-resistance insulator ruptures to a specific region to improve consistency of post-programming resistance of the OTP memory 200. The OTP memory 200 also requires a minimum of only two electrodes instead of a minimum of three electrodes. Thus, the OTP memory 200 is smaller than conventional MOSFET antifuse devices.

Referring to FIG. 2A, the OTP memory 200 is fabricated on a substrate 202. Fabrication of the OTP memory 200 is by a CMOS-compatible manufacturing process. The substrate 202 may generally be comprised of materials such as, and not limited to, silicon, silicon on insulator, gallium arsenide, or sapphire. The substrate 202 may be a P-type substrate, for example, a silicon substrate may be doped with acceptors to a dopant concentration of 5×10¹⁴cm⁻³ to 5×10¹⁵ cm⁻³. High-resistance insulator ruptures may be partially mitigated by using a lightly doped substrate as further described in U.S. Pat. Nos. 6,700,176 and 6,902,958, incorporated herein by reference in their entireties.

The substrate 202 may optionally contain a P-type well or an N-type well, such as a well located in a region of the substrate between the STI region 204 and an optional second STI region 206. The well may be proximate to the STI region 204 and the optional second STI region 206. Exemplary dopant concentrations for the optional well are 10¹⁶ cm⁻³ to 10¹⁸ cm⁻³. Dopant concentrations referred to herein only examples and other dopant concentrations may be used. Doping is performed by ion implantation or other doping techniques, and activation annealing.

The substrate 202 contains the STI region 204. The STI region 204 is an insulator for the purpose of isolating different parts of the substrate. A number of isolation methods can be used and are not limited to shallow trench isolation. The STI region 204 directs formation of insulator ruptures to a specific region to improve consistency of post-programming resistance of the OTP memory 200. Degraeve et al have shown that post-programming resistance is clearly influenced by rupture, or breakdown, location. For details, see R. Degrave et al, “Relation between breakdown mode and location in short channel NMOSFETs and its impact on reliability specifications”, IEEE Transactions On Device and Materials Reliability, Vol. 1-3, September 2001, pp. 13-169, which is incorporated herein by reference.

During programming, at least one diffused electrode 208 creates an electric field across the insulator 214. The diffused electrode 208 is an region that is highly doped, N+ or P+, relative to the substrate, with either donors or acceptors and is the only well required by the OTP memory 200. Exemplary dopant concentrations for the diffused electrode 208 are 10¹⁹ cm⁻³ to 10²⁰cm⁻³. A first contact 210 is coupled to the diffused electrode 208. The first contact 210 couples the diffused electrode 208 to circuits that program the OTP memory 200 and circuits that read stored information from the OTP memory 200.

The diffused electrode 208 may also include an implant region 212. The implant region 212 extends from the diffused electrode 208 toward the STI region 204. It is desirable to have implant region 212 touch the STI region 204, but it is not required. The implant region 212 may be doped with donors or acceptors. Exemplary dopant concentrations for the implant region 212 are 10¹⁷ cm⁻³ to 10¹⁹ cm⁻³. Relative to the diffused electrode 208, the implant region 212 may be lightly doped to provide a consistent resistance when the OTP memory has been programmed.

The insulator 214 is deposited on the substrate 202, the STI region 204, the second STI region 206, the diffused electrode 208, and the implant region 212. The insulator 214 is a dielectric layer such as an oxide layer and/or a nitride layer. In this context, an oxide layer would include material such as hafnium oxide. In an example, the nitride layer is atop the oxide layer. In a further example, the oxide layer is atop the nitride layer. Characteristics of the insulator 214, such as a dielectric breakdown voltage, determine the minimum electric field necessary to program the OTP memory 200.

The OTP memory 200 also has a second electrode 216 to create an electric field across the insulator 214 during programming. As illustrated in FIG. 2A, the insulator 214 separates the second electrode 216 from the diffused electrode 208 and the STI region 204. At least a part of the second electrode 216 overlaps at least a part of the STI region 204. If the OTP memory 200 contains the implant region 212, the insulator 214 separates the second electrode 216 from the implant region 212. At least a part of the second electrode 216 may overlap at least a part of the implant region 212. The second electrode 216 is a conductive material, such as metal or heavily doped polysilicon, having an exemplary dopant concentration of 10²⁰ cm⁻³ to 10²² cm⁻³.

A second contact 218 is coupled to the second electrode 216. The second contact 218 couples the second electrode 216 to circuits that program the OTP memory 200 and read stored information from the OTP memory 200.

In order to achieve a high density memory or other memory circuit with multiple OTP memories, such as a redundant memory or a memory having error correction, an antifuse structure should be as small as possible. Unlike the conventional MOSFET 100, the OTP memory 200 requires only one diffused electrode 208 and is thus relatively smaller in size. Therefore, the OTP memory 200 is denser than an antifuse made from the conventional MOSFET 100. For example, in an 65 nm process, the OTP memory 200 is approximately 40% smaller than the conventional MOSFET 100. The OTP memory 200 structure is also scalable and thus not limited to fabrication with a process feature size of 65 nm. The OTP memory 200 may also be manufactured with process feature sizes such as 13 μm and 45 nm, as well as other process feature sizes including sizes smaller than 45 nm. Further, multiple OTP memories 200 may be coupled in parallel to provide redundant clusters of high-reliability memory cells.

FIG. 2B illustrates a top view of the OTP memory 200. FIG. 2B does not illustrate the insulator 214 to assist in further illustrating overlap of an active region 220 by the second electrode 216. The active region 220 is a region that includes the diffused electrode 208 and the implant region 212. Dimension “A” indicates the overlap of the active region 220 by the second electrode 216. Dimension “B” indicates clearance of the active region 220 from the second electrode 216. The dimension “B” may be positive, zero, or negative. The dimension “A” may be scaled to as small as the alignment tolerance of the second electrode 216 to the active region 220. The dimension “A” may, therefore, be much smaller than the minimum gate length of a given process geometry, thus making the OTP memory 200 the smallest possible antifuse in any process technology. The OTP memory 200 has higher security than the conventional MOSFET 100 because the relatively smaller size of the OTP memory 200 makes reverse engineering much more difficult.

FIG. 2C illustrates how the STI region 204 improves consistency of post-programming OTP memory 200 resistance. An edge 222 of the STI region 204 is one place where the STI region 204 interacts with the second electrode 216 across the insulator 214. The breakdown voltage of the STI region 204 is much greater than that of the insulator 214, so the STI region 204 concentrates an applied electric field to force a rupture of the insulator 214 to occur near the edge 222. Thus, ruptures consistently occur in a narrowly targeted region and have low variability of post-programming resistance. Therefore, the STI region 204 improves ease of OTP memory 200 programming and consistency of post-programming OTP memory 200 resistance. Ruptures in the OTP memory 200 are also very small and hard to see under optical magnification, so reverse engineering of a programmed OTP memory 200 is very difficult.

In comparison, the conventional MOSFET 100 has a shallow trench isolation region having multiple edges which leads to scattered ruptures of the polysilicon gate 102 and high variability of post-programming resistance. The OTP memory 200 eliminates these multiple edges and replaces them with only one edge 222.

The OTP memory 200 is programmed by stressing the insulator 214 beyond a critical electric field to rupture the insulator 214. The critical electric field is a threshold at which rupture of the insulator 214 occurs and is determined by dividing a voltage applied across the insulator 214 by the thickness of the insulator 214. When the insulator 214 ruptures, a resistance between the diffused electrode 208 and the second electrode 216 is greatly reduced from that of a non-ruptured insulator 214. The resistance decreases because a rupture of the insulator 214 forms a current path by diffusing polysilicon material from the second electrode 216 and/or silicon from the substrate 202 into the insulator 214.

A programming circuit is coupled to the first contact 210 and the second contact 218 to program the OTP memory 200. Prior to programming, the OTP memory 200 is an open circuit. To program a data bit into the OTP memory, the programming circuit provides either zero voltage or a voltage across the insulator 214 in excess of the critical electric field. If zero voltage is applied, the programming circuit programs a first state, such as a logic zero. If a voltage in excess of the critical electric field is applied to rupture the insulator 214 and short the diffused electrode 208 to the second electrode 216, the programming circuit programs a second state, such as a logic one. Alternatively, the first state may represent a logic one and the second state may represent a logic zero.

A circuit to read a previously-programmed OTP memory 200 is also coupled to the first contact 210 and the second contact 218. After programming, the OTP memory 200 does not conduct current flow if the first state has been programmed. If the second state has been programmed, then the OTP memory 200 does conduct current flow. The OTP memory 200 is read with an applied voltage less that of the critical electric field so that the process of reading does not inadvertently program the OTP memory 200. Reading the OTP memory 200 does not change previous programming of the OTP memory 200.

FIGS. 2A-C illustrate ideal structures and are not to scale.

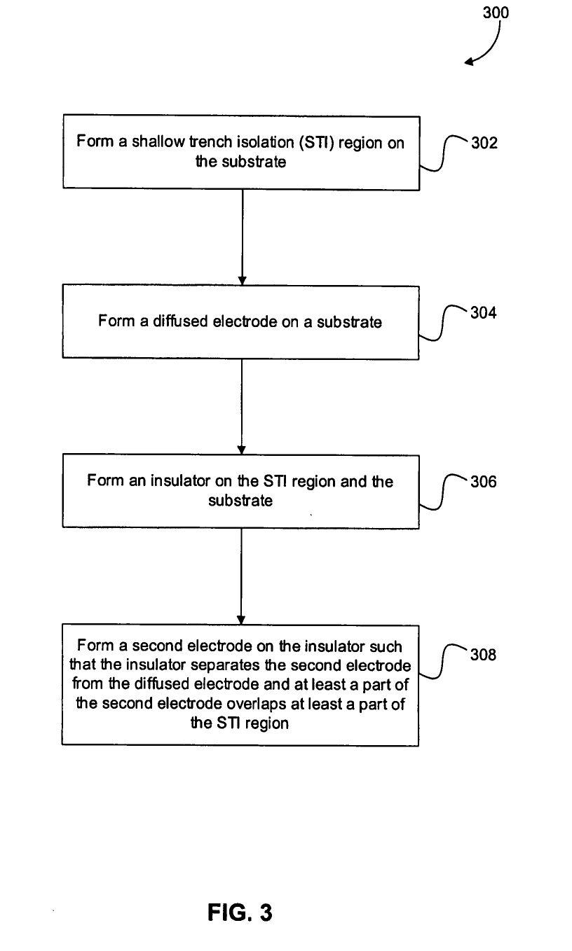

FIG. 3 is a flowchart of an exemplary method for manufacturing an OTP memory such as the OTP memory 200. In step 302, an STI region is formed on a substrate. The STI region may be formed by trench etching in the substrate, followed by deposition of an insulator such as silicon dioxide into the trench.

In step 304, a diffused electrode is formed on a substrate. During formation, the diffused electrode may be highly doped. For example, a high dose of dopant is implanted into a Pwell, an Nwell, or a lightly doped p-substrate to form the heavily doped diffused electrode. The diffused electrode may be formed by ion implantation or another doping method, followed by annealing. If the substrate itself is doped or a well is deposited on a part of the substrate, the diffused electrode may be doped with a dopant having polarity opposite that of the substrate or the well. A contact may deposited on the diffused electrode.

In step 306, a insulator is formed on the STI region and the substrate. The insulator separates the implant region and the second electrode. The insulator may be formed of at least one of an oxide layer and a nitride layer.

In step 308, a second electrode is formed on the insulator such that the insulator separates the second electrode from the diffused electrode and at least a part of the second electrode overlaps at least a part of the STI region. A contact may be deposited on the second electrode. The contact may be formed on the STI region so that a size of the OTP memory may be minimized. Optionally, after the second electrode is defined, the implant region may be formed by ion implantation.

After formation of the insulator, the OTP memory may be programmed, also known as fusing. The P-substrate or N-type well may be floated during fusing, which enhances formation of ruptures, also known as fusing paths, between the second electrode and the heavily doped diffused electrode.

The OTP memories described herein may be manufactured with a CMOS logic manufacturing process without adding masking steps beyond those required to manufacture a MOSFET. Similar to MOSFET fabrication, the OTP memory 200 may be manufactured with dopant polarities opposite of those recited herein.

### CONCLUSION

Example embodiments of the methods, systems, and components of the present invention are described herein. As noted elsewhere, these example embodiments are described for illustrative purposes only, and are not limiting. Other embodiments are possible and are covered by the invention. Such other embodiments will be apparent to persons skilled in the relevant art(s) based on the teachings contained herein. Thus, the breadth and scope of the present invention are not limited by any of the above-described exemplary embodiments, but are defined only in accordance with the following claims and their equivalents.

What is claimed is:

1. A one-time programmable memory, comprising:
a substrate;
a diffused electrode disposed on said substrate;
a shallow trench isolation (STI) region formed on said substrate;
a insulator on said STI region and said substrate; and
a second electrode;
wherein said insulator separates said second electrode from said diffused electrode;
wherein at least a part of said second electrode overlaps at least a part of said STI.

2. The memory of claim 1, wherein said diffused electrode is highly-doped relative to said substrate.

3. The memory of claim 1, wherein said substrate has a dopant polarity opposite a dopant polarity of said diffused electrode.

4. The memory of claim 1, wherein said substrate has a dopant polarity the same as the dopant polarity of said diffused electrode.

5. The memory of claim 1, wherein said diffused electrode further comprises an implant region extending from said diffused electrode toward said STI region.

6. The memory of claim 4, wherein said insulator separates said implant region from said second electrode and said implant region has a dopant concentration between 10¹⁷ cm⁻³ to 10¹⁹ cm⁻³.

7. The memory of claim 4, wherein at least a part of said second electrode overlaps at least a part of said implant region.

8. The memory of claim 4, wherein said implant region is lightly doped relative to said diffused electrode.

9. The memory of claim 1, wherein said insulator includes at least one of an oxide layer and a nitride layer.

10. The memory of claim 1, further comprising a contact coupled to said second electrode.

11. The memory of claim 1, further comprising a contact coupled to said diffused electrode.

12. A method for manufacturing a one-time programmable memory having a substrate, a diffused electrode, a shallow trench isolation (STI) region, an insulator, and a second electrode, comprising:
forming the diffused electrode on the substrate;
forming the STI region on the substrate;
forming the insulator on the STI region and the substrate; and
forming the second electrode on the insulator such that the insulator separates the second electrode from the diffused electrode and at least a part of the second electrode overlaps at least a part of the STI region.

13. The method of claim 12, wherein said forming the diffused electrode further comprises highly-doping the diffused electrode.

14. The method of claim 12, wherein said forming the diffused electrode further comprises doping the diffused electrode with a dopant polarity opposite that of the substrate.

15. The method of claim 12, where the one-time programmable memory element has a lightly-doped implant region extending from the diffused electrode toward the STI region, further comprising forming the lightly-doped implant region.

16. The method of claim 15, wherein said forming the insulator further comprises forming the insulator between the implant region and the second electrode.

17. The method of claim 16, wherein said forming the second electrode further comprises forming the second electrode such that at least a part of the second electrode overlaps at least a part of the implant region.

18. The method of claim 12, wherein said forming the insulator further comprises forming at least one of a nitride layer and an oxide layer.
